(19) United States
(12) Patent Application Publication
(10) Pub. No.: US 2026/0096448 A1
(43) Pub. Date: Apr. 2, 2026

(54) SEMICONDUCTOR DEVICE

(71) Applicant: Rohm Co., Ltd., Kyoto-shi (JP)

(72) Inventor: Tomohira KIKUCHI, Kyoto-shi (JP)

(21) Appl. No.: 19/412,003

(22) Filed: Dec. 8, 2025

Related U.S. Application Data
(63) Continuation of application No. PCT/JP2024/018096, filed on May 16, 2024.

(30) Foreign Application Priority Data
Jun. 13, 2023 (JP) 2023-096748

(51) Int. Cl. H10W 70/40; H10W 74/10; H10W 90/00; H10W 90/10

(52) U.S. Cl. CPC H10W 70/417; H10W 74/114; H10W 90/10; H10W 90/811; H10W 90/736; H10W 90/753; H10W 90/756

(57) ABSTRACT

A semiconductor device includes a first die pad, a first semiconductor element, a first lead, a first conductive member, and a sealing resin. The first conductive member is conductively bonded to the first semiconductor element and the first lead. The first die pad, the first semiconductor element, and the first conductive member are covered with the sealing resin. The first lead protrudes from the first side surface of the sealing resin. The first distance D1, the second distance D2, and the third distance D3 satisfy the relationship D1>D2≥D3. In the first direction z, the first conductive member is located between the first mounting surface of the first die pad and the top surface of the sealing resin.

### TECHNICAL FIELD

The present disclosure relates to a semiconductor device

### BACKGROUND ART

The semiconductor device disclosed in JP-A-2016-207714 includes two die pads, a control element (controller) and a drive element (gate driver) individually mounted on the two die pads, and a sealing resin covering the two die pads, the control element and the drive element. The semiconductor device drives switching elements, such as IGBTs or MOSFETs. The semiconductor device is used in an inverter circuit, for example.

In the semiconductor device, the power supply voltage supplied to the drive element is equal to or greater than the voltage applied to the switching element, so that the power supply voltage supplied to the control element and the power supply voltage supplied to the drive element differ from each other. This results in a difference between the voltage applied to the control element and its conduction path and the voltage applied to the drive element and its conduction path. In the semiconductor device, an insulating element is interposed in the electric signal transmission path between the control element and the drive element to insulate the control element and its conductive path and the drive element and its conductive path from each other. This prevents electric breakdown of the control element and the drive element.

The semiconductor device further includes wires conductively bonded to either the control element or the drive element and a terminal. When the size of the semiconductor device is made smaller, or the size of each of the control element and the drive element is made larger without changing the size of the semiconductor device, a thickness of the sealing resin over the wires becomes smaller. There is a concern that the dielectric strength of the semiconductor device may decrease if such a covering portion becomes smaller.

### BRIEF DESCRIPTION OF THE DRAWINGS

FIG. 1 is a plan view of a semiconductor device according to a first embodiment of the present disclosure.

FIG. 2 is a plan view corresponding to FIG. 1, in which the sealing resin is transparent.

FIG. 3 is a front view of the semiconductor device shown in FIG. 1.

FIG. 4 is a rear view of the semiconductor device shown in FIG. 1.

FIG. 5 is a left side view of the semiconductor device shown in FIG. 1.

FIG. 6 is a right-side view of the semiconductor device shown in FIG. 1.

FIG. 7 is a sectional view taken along line VII-VII in FIG. 2.

FIG. 8 is a sectional view taken along line VIII-VIII in FIG. 2.

FIG. 9 is a sectional view taken along line IX-IX in FIG. 2.

FIG. 10 is a plan view of a semiconductor device according to a second embodiment of the present disclosure, in which the sealing resin is transparent.

FIG. 11 is a sectional view taken along line XI-XI in FIG. 10.

FIG. 12 is a plan view of a semiconductor device according to a third embodiment of the present disclosure.

FIG. 13 is a plan view corresponding to FIG. 12, in which the sealing resin is transparent.

FIG. 14 is a front view of the semiconductor device shown in FIG. 12.

FIG. 15 is a left side view of the semiconductor device shown in FIG. 12.

FIG. 16 is a sectional view taken along line XVI-XVI in FIG. 13.

### DETAILED DESCRIPTION

The present disclosure is described below in detail based on the accompanying drawings

### First Embodiment:

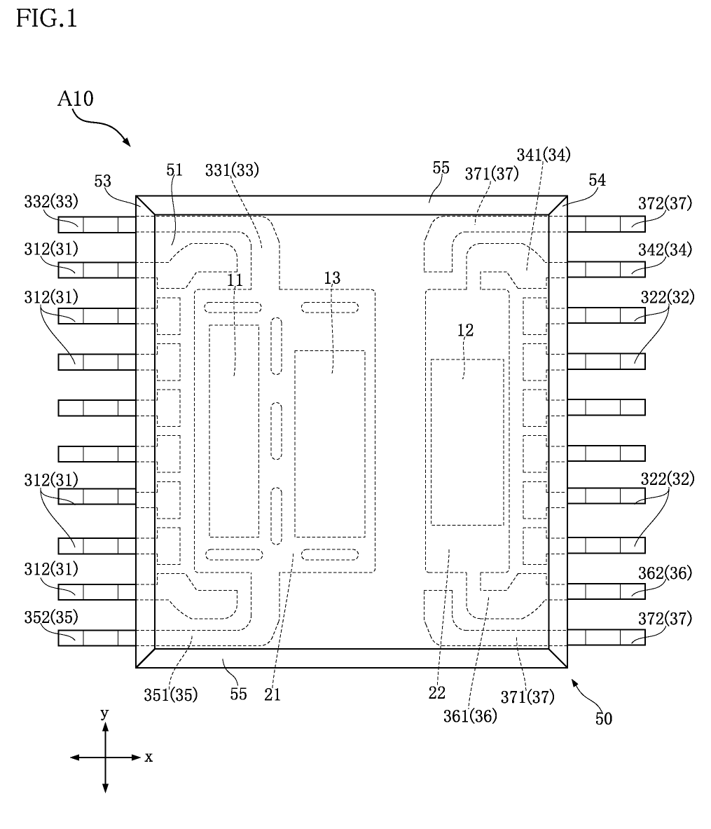

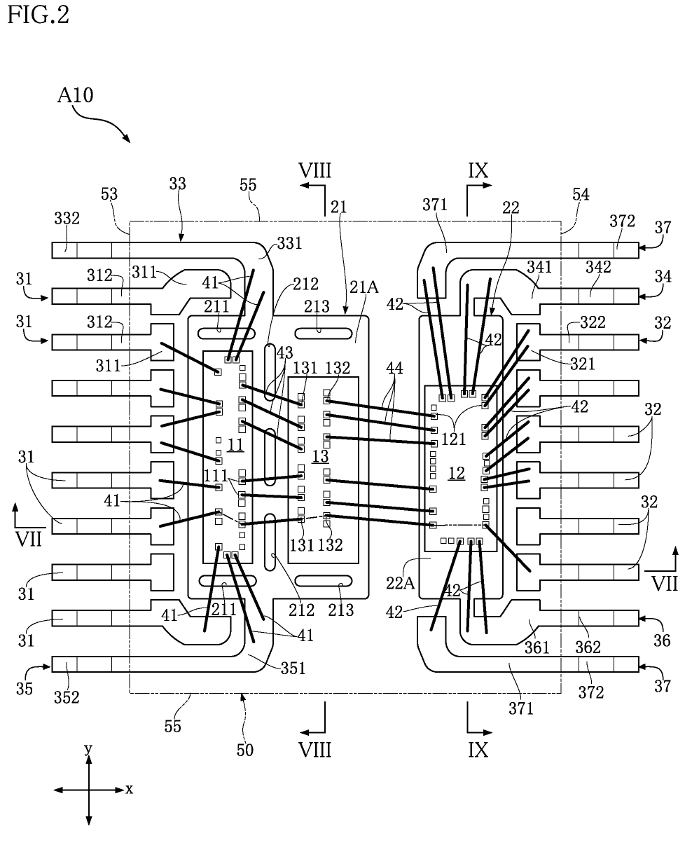

A semiconductor device A10 according to a first embodiment of the present disclosure will be described based on FIGS. 1 to 9. The semiconductor device A10 includes a first semiconductor element 11, a second semiconductor element 12, an insulating element 13, a first die pad 21, a second die pad 22, a plurality of first leads 31, a plurality of second leads 32, and a sealing resin 50. The semiconductor device A10 further includes a third lead 33, a fourth lead 34, a fifth lead 35, a sixth lead 36, two seventh leads 37, a plurality of first conductive members 41, a plurality of second conductive members 42, a plurality of third conductive members 43, and a plurality of fourth conductive members 44. The semiconductor device A10 may be surface-mounted on a circuit board of an inverter device, for example, in an electric vehicle or a hybrid vehicle. The package type of the semiconductor device A10 is SOP (Small Outline Package). However, the package type of the semiconductor device A10 is not limited to SOP. For convenience of understanding, the sealing resin 50 is transparent in FIG. 2. In FIG. 2, the outlines of the sealing resin 50 are shown by imaginary lines (two-dot chain lines).

In the description of the semiconductor device A10, the direction that is normal to the first mounting surface 21A of the first die pad 21, described later, is referred to as the "first direction z" for convenience. A direction orthogonal to the first direction z is referred to as the "second direction x". The direction orthogonal to the first direction z and the second direction x is referred to as the "third direction y".

In the semiconductor device A10, the first semiconductor element 11, the second semiconductor element 12, and the insulating element 13 are individual elements. The second semiconductor element 12 is located opposite to the first semiconductor element 11 with respect to the insulating element 13 in the second direction x. The insulating element 13 is located next to the first semiconductor element 11 in the third direction y. As viewed in the first direction z (in plan view), each of the first semiconductor element 11, the second semiconductor element 12, and the insulating element 13 is rectangular with the long side extending in the third direction y.

The first semiconductor element 11 controls the second semiconductor element 12. The first semiconductor element 11 includes a circuit for converting electrical signals inputted from other semiconductor devices into PWM control signals, a transmission circuit for transmitting the PWM control signals to the second semiconductor element 12, and a reception circuit for receiving electrical signals from the second semiconductor element 12.

The second semiconductor element 12 drives a switching element located outside the semiconductor device A10. The switching elements may be, for example, an IGBT (Insulated Gate Bipolar Transistor) or a MOSFET (Metal-Oxide-Semiconductor Field-Effect Transistor). The second semiconductor element 12 includes a receiving circuit for receiving PWM control signals, a circuit for driving the switching element based on the PWM control signals, and a transmission circuit for transmitting electrical signals to the first semiconductor element 11. Examples of the electrical signals include an output signal from a temperature sensor disposed near the motor.

The insulating element 13 transmits electrical signals, such as PWM (Pulse Width Modulation) control signals, in an insulated condition. The insulating element 13 is of an inductively coupled type. An example of the inductively coupled insulating element 13 is an isolation transformer. An isolation transformer includes two inductively coupled inductors (coils) to realize transmission of electric signals in an insulated state. The two inductors include a transmitting-side inductor and a receiving-side inductor. The two inductors are laminated in the first direction z. A dielectric layer made of silicon dioxide (SiO₂), for example, is disposed between the transmitting-side inductor and the receiving-side inductor. The dielectric layer provides electrical insulation between the transmitting-side inductor and the receiving-side inductor. Alternatively, the insulating element 13 may be of a capacitive type. An example of a capacitive insulating element 13 is a capacitor.

The voltage applied to the first semiconductor element 11 and the voltage applied to the second semiconductor element 12 are different from each other. Thus, there is a potential difference between the first semiconductor element 11 and the second semiconductor element 12. In the semiconductor device A10, the voltage applied to the second semiconductor element 12 is higher than the voltage applied to the first semiconductor element 11. Also, in the semiconductor device A10, the power supply voltage supplied to the second semiconductor element 12 is higher than the power supply voltage supplied to the first semiconductor element 11.

In the semiconductor device A10, a first circuit including the first semiconductor element and a second circuit including the second semiconductor element 12 are insulated from each other by the insulating element 13. The insulating element 13 is electrically connected to the first circuit and the second circuit. The first circuit includes the first leads 31, the third lead 33, and the fifth lead 35, in addition to the first semiconductor element 11. The second circuit includes the second leads 32, the fourth lead 34, and the sixth lead 36, in addition to the second semiconductor element 12. The first circuit and the second circuit have different potentials. In the semiconductor device A10, the potential of the first circuit is higher than the potential of the second circuit. The insulating element 13 relays signals between the first circuit and the second circuit. For example, in an inverter device for an electric vehicle or a hybrid vehicle, the voltage applied to the ground (GND) of the second semiconductor element 12 may transiently become 600 V or higher while the voltage applied to the ground of the first semiconductor element 11 is about 0 V.

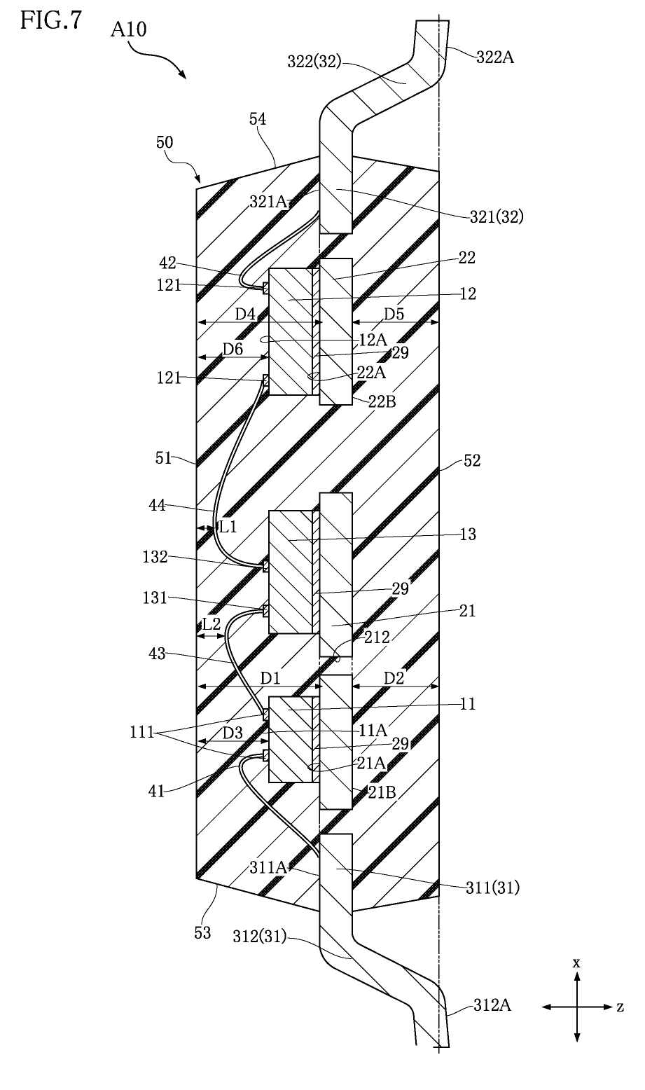

As shown in FIG. 7, the first semiconductor element 11 has a first element surface 11A that faces the same side in the first direction z as the first mounting surface 21A of the first die pad 21, described later. As shown in FIGS. 2 and 7, the first semiconductor element 11 has a plurality of first electrodes 111. The first electrodes 111 are disposed on the first element surface 11A. The first electrodes 111 contain, for example, aluminum (Al). The first electrodes 111 are electrically connected to the circuit formed in the first semiconductor element 11.

As shown in FIG. 7, the second semiconductor element 12 has a second element surface 12A that faces the same side in the first direction z as the second mounting surface 22A of the second die pad 22, described later. As shown in FIGS. 2, 7 and 9, the second semiconductor element 12 has a plurality of second electrodes 121. The second electrodes 121 are disposed on the second element surface 12A. The second electrodes 121 contain, for example, aluminum. The second electrodes 121 are electrically connected to the circuit formed in the second semiconductor element 12.

As shown in FIGS. 2 and 7, the insulating element 13 is located between the second semiconductor element 12 and the first semiconductor element 11 in the second direction x. In other words, the first semiconductor element 11 is located opposite to the second semiconductor element 12 with respect to the insulating element 13 in the second direction x. A plurality of third electrodes 131 and a plurality of fourth electrodes 132 are provided on one side of the insulating element 13 in the first direction z (i.e., on the side which the first element surface 11A of the first semiconductor element 11 faces in the first direction z). The third electrodes 131 and the fourth electrodes 132 are electrically connected to the transmitting-side inductor or the receiving-side inductor. The third electrodes 131 are arranged along the third direction y and located between the first semiconductor element 11 and the second semiconductor element 12 in the second direction x. The fourth electrodes 132 are arranged along the third direction y and located opposite to the first semiconductor element 11 with respect to the third electrodes 131 in the second direction x. The third electrodes 131 and the fourth electrodes 132 contain, for example, aluminum.

As shown in FIG. 1, the sealing resin 50 covers the first semiconductor element 11, the second semiconductor element 12, the insulating element 13, the first die pad 21, and the second die pad 22. As shown in FIG. 7, the sealing resin 50 also covers the first conductive members 41, the second conductive members 42, the third conductive members 43, and the fourth conductive members 44. The sealing resin 50 is an insulator. The sealing resin 50 is made of a material containing, for example, epoxy resin. The sealing resin 50 is rectangular as viewed in the first direction z.

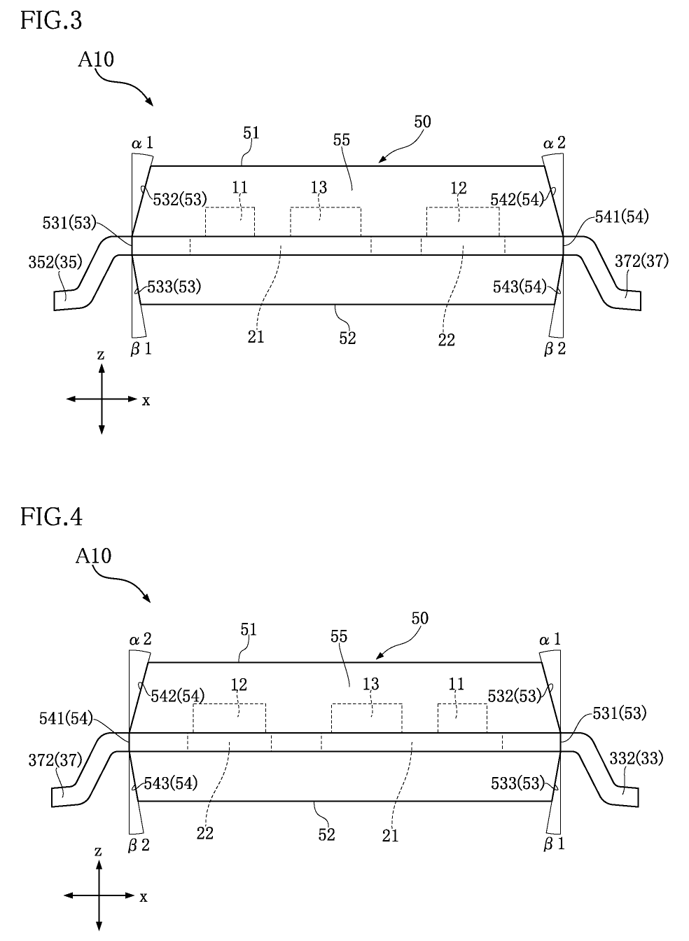

As shown in FIGS. 3 to 6, the sealing resin 50 has a top surface 51, a bottom surface 52, a first side surface 53, a second side surface 54, and two third side surfaces 55.

As shown in FIGS. 3 to 6, the top surface 51 and the bottom surface 52 face away from each other in the first direction z. The top surface 51 faces the same side in the first direction z as the first mounting surface 21A of the first die pad 21, described later.

As shown in FIGS. 3 and 4, the first side surface 53 is connected to the top surface 51 and the bottom surface 52 and faces one side in the second direction x. The first side surface 53 is located closer to the first die pad 21 than is the second side surface 54. The first side surface 53 includes a first region 531, a second region 532, and a third region 533. The first region 531 extends in the first direction z in-plane. As viewed in the first direction z, the first region 531 is located outward from each of the top surface 51 and the bottom surface 52. The second region 532 is located between the first region 531 and the top surface 51 in the first direction z. The third region 533 is located opposite to the second region 532 with respect to the first region 531. Each of the second region 532 and the third region 533 is inclined with respect to the first region 531. The inclination angle α1 of the second region 532 with respect to the first region 531 is greater than the inclination angle β1 of the third region 533 with respect to the first region 531.

As shown in FIGS. 3 and 4, the second side surface 54 is connected to the top surface 51 and the bottom surface 52 and faces away from the first side surface 53 in the second direction x. The second side surface 54 is located closer to the second die pad 22 than is the first side surface 53. The second side surface 54 includes a fourth region 541, a fifth region 542, and a sixth region 543. The fourth region 541 extends in the first direction z in-plane. As viewed in the first direction z, the fourth region 541 is located outward from each of the top surface 51 and the bottom surface 52. The fifth region 542 is located between the fourth region 541 and the top surface 51 in the first direction z. The sixth region 543 is located opposite to the fifth region 542 with respect to the fourth region 541. Each of the fifth region 542 and the sixth region 543 is inclined with respect to the fourth region 541. The inclination angle α2 of the fifth region 542 with respect to the fourth region 541 is greater than the inclination angle β2 of the sixth region 543 with respect to the fourth region 541.

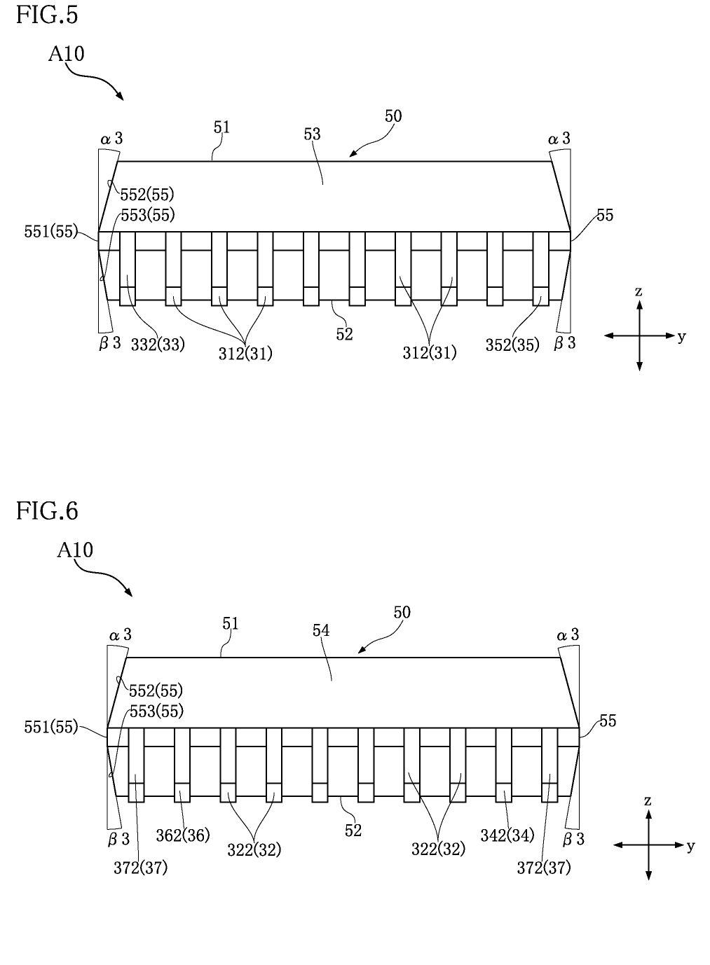

As shown in FIGS. 5 and 6, the two third side surfaces 55 are connected to the top surface 51 and the bottom surface 52 and face away from each other in the third direction y. Each of the two third side surfaces 55 includes a seventh region 551, an eighth region 552, and a ninth region 553. The seventh region 551 extends in the first direction z in-plane. As viewed in the first direction z, the seventh region 551 is located outward from each of the top surface 51 and the bottom surface 52. The eighth region 552 is located between the seventh region 551 and the top surface 51 in the first direction z. The ninth region 553 is located opposite to the eighth region 552 with respect to the seventh region 551. Each of the eighth region 552 and the ninth region 553 is inclined with respect to the seventh region 551. The inclination angle α3 of the eighth region 552 with respect to the seventh region 551 is greater than the inclination angle β3 of the ninth region 553 with respect to the seventh region 551.

The first die pad 21, the second die pad 22, the first leads 31, the second leads 32, the third lead 33, the fourth lead 34, the fifth lead 35, the sixth lead 36, and the two seventh leads 37 all contain copper (Cu). The first die pad 21, the second die pad 22, and these leads are obtained from the same lead frame.

As shown in FIGS. 1 and 2, the first die pad 21 and the second die pad 22 are spaced apart from each other in the second direction x. In the semiconductor device A10, the first semiconductor element 11 and the insulating element 13 are mounted on the first die pad 21, and the second semiconductor element 12 is mounted on the second die pad 22. In this case, as viewed in the first direction z, the area of the first die pad 21 is larger than the area of the second die pad 22. Unlike the illustrated example, the first semiconductor element 11 may be mounted on the first die pad 21, and the second semiconductor element 12 and the insulating element 13 may be mounted on the second die pad 22.

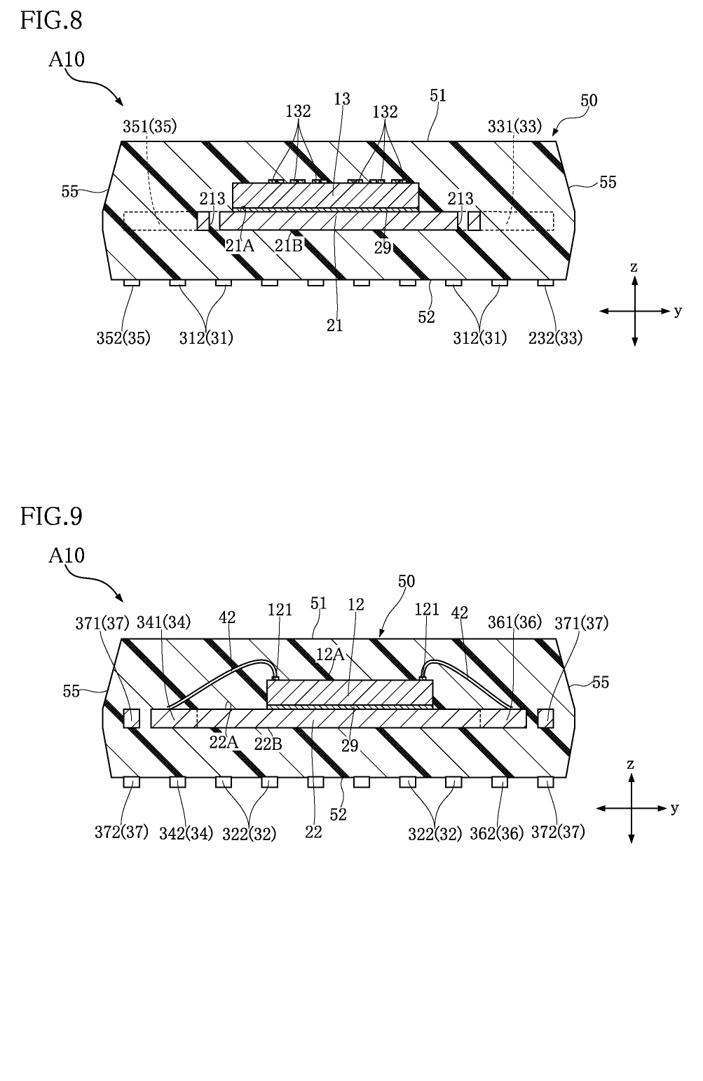

As shown in FIGS. 7 and 8, the first die pad 21 has a first mounting surface 21A and a first reverse surface 21B facing away from each other in the first direction z. The first mounting surface 21A faces the same side in the first direction z as the top surface 51 of the sealing resin 50. Each of the first semiconductor element 11 and the insulating element 13 is bonded to the first mounting surface 21A via a bonding layer 29. The bonding layer 29 is made of a paste containing metal particles. The metal particles are, for example, silver (Ag). Thus, the bonding layers 29 are conductors. Alternatively, the bonding layers 29 may be solder.

As shown in FIG. 7, the distance in the first direction z between the first mounting surface 21A of the first die pad 21 and the top surface 51 of the sealing resin 50 is defined as a first distance D1. The distance in the first direction z between the first reverse surface 21B of the first die pad 21 and the bottom surface 52 of the sealing resin 50 is defined as a second distance D2. The distance in the first direction z between the first element surface 11A of the first semiconductor element 11 and the top surface 51 is defined as a third distance D3. In this state, the relationship D1>D2≥D3 is satisfied.

As shown in FIGS. 2, 7, and 8, the first die pad 21 has two first holes 211, a plurality of second holes 212, and two third holes 213. Each of the two first holes 211, the second holes 212, and the two third holes 213 penetrates the first die pad 21 in the first direction z. The two first holes 211 are located on opposite sides of the first semiconductor element 11 in the third direction y. Each of the two first holes 211 extends in the second direction x. The second holes 212 are located between the first semiconductor element 11 and the insulating element 13 in the second direction x. Each of the second holes 212 extends in the third direction y. The second holes 212 are arranged along the third direction y. The two third holes 213 are located on opposite sides of the insulating element 13 in the third direction y. Each of the two third holes 213 extends in the second direction x.

As shown in FIGS. 7 and 9, the second die pad 22 has a second mounting surface 22A and a second reverse surface 22B facing away from each other in the first direction z. The second mounting surface 22A faces the same side in the first direction z as the first mounting surface 21A of the first die pad 21. The second semiconductor element 12 is bonded to the second mounting surface 22A via a bonding layer 29.

As shown in FIG. 7, the distance in the first direction z between the second mounting surface 22A of the second die pad 22 and the top surface 51 of the sealing resin 50 is defined as a fourth distance D4. The distance in the first direction z between the second reverse surface 22B of the second die pad 22 and the bottom surface 52 of the sealing resin 50 is defined as a fifth distance D5. The distance in the first direction z between the second element surface 12A of the second semiconductor element 12 and the top surface 51 is defined as a sixth distance D6. In this state, the relationship D4>D5≥D6 is satisfied.

As shown in FIGS. 1 and 2, the first leads 31 are located between the third lead 33 and the fifth lead 35 in the third direction y. The first leads 31 are located opposite to the second die pad 22 with respect to the first die pad 21 in the second direction x. The first leads 31 are arranged along the third direction y. At least one of the first leads 31 is electrically connected to the first semiconductor element 11.

As shown in FIGS. 2 and 7, each of the first leads 31 has a first inner portion 311 and a first outer portion 312. The first inner portion 311 is covered with the sealing resin 50. As shown in FIG. 7, the first inner portion 311 has a first connection surface 311A. The first connection surface 311A faces the same side in the first direction z as the first mounting surface 21A of the first die pad 21. The first connection surface 311A and the first mounting surface 21A are contained in the same plane. The first outer portion 312 is connected to the first inner portion 311. The first outer portion 312 protrudes from the first region 531 of the first side surface 53 of the sealing resin 50. As viewed in the first direction z, the first outer portion 312 extends in the second direction x. The first outer portion 312 is bent in a gull wing shape as viewed in the third direction y. The shape of the first outer portion 312 is the same as the shape of the third outer portion 332 (see FIG. 4) of the third lead 33, described later. The surface of the first outer portion 312 may be plated with, for example, tin.

As shown in FIG. 7, the first outer portion 312 has a first attachment surface 312A. The first attachment surface 312A faces away from the first connection surface 311A of the first inner portion 311 in the first direction z. The first attachment surface 312A is located farthest from the first connection surface 311A in the first direction z. The first attachment surface 312A protrudes from the plane containing the bottom surface 52 of the sealing resin 50. The first attachment surface 312A is inclined with respect to the bottom surface 52.

As shown in FIGS. 1 and 2, the third lead 33 includes a portion extending toward the first die pad 21 and is located closest to one of the two third side surfaces 55 of the sealing resin 50. The third lead 33 is connected to one side in the third direction y of the first die pad 21. The third lead 33 is spaced apart from each of the two third side surfaces 55. The third lead 33 has a third inner portion 331 and a third outer portion 332. The third inner portion 331 is connected to the first die pad 21 and covered with the sealing resin 50. The third outer portion 332 is connected to the third inner portion 331. The third outer portion 332 protrudes from the first region 531 of the first side surface 53 of the sealing resin 50. As viewed in the first direction z, the third outer portion 332 extends in the second direction x. As shown in FIG. 4, the third outer portion 332 is bent in a gull wing shape as viewed in the third direction y. The surface of the third outer portion 332 may be plated with, for example, tin.

As shown in FIGS. 1 and 2, the fifth lead 35 includes a portion extending toward the first die pad 21 and is located closest to one of the two third side surfaces 55 of the sealing resin 50. The fifth lead 35 is connected to the side in the third direction y of the first die pad 21 that is opposite to the side where the third lead 33 is located. The fifth lead 35 is spaced apart from each of the two third side surfaces 55. The fifth lead 35 has a fifth inner portion 351 and a fifth outer portion 352. The fifth inner portion 351 is connected to the first die pad 21 and covered with the sealing resin 50. The fifth outer portion 352 is connected to the fifth inner portion 351. The fifth outer portion 352 protrudes from the first region 531 of the first side surface 53 of the sealing resin 50. As viewed in the first direction z, the fifth outer portion 352 extends in the second direction x. As shown in FIG. 3, the fifth outer portion 352 is bent in a gull wing shape as viewed in the third direction y. The surface of the fifth outer portion 352 may be plated with, for example, tin.

As shown in FIG. 8, as viewed in the third direction y, each of the third inner portion 331 of the third lead 33 and the fifth inner portion 351 of the fifth lead 35 overlaps with the first die pad 21.

As shown in FIGS. 1 and 2, the second leads 32 are located between the fourth lead 34 and the sixth lead 36 in the third direction y. The second leads 32 are located opposite to the first die pad 21 with respect to the second die pad 22 in the second direction x. The second leads 32 are arranged along the third direction y. At least one of the second leads 32 is electrically connected to the second semiconductor element 12.

As shown in FIGS. 2 and 7, each of the second leads 32 has a second inner portion 321 and a second outer portion 322. The second inner portion 321 is covered with the sealing resin 50. As shown in FIG. 7, the second inner portion 321 has a second connection surface 321A. The second connection surface 321A faces the same side in the first direction z as the second mounting surface 22A of the second die pad 22. The second connection surface 321A and the second mounting surface 22A are contained in the same plane. The second outer portion 322 is connected to the second inner portion 321. The second outer portion 322 protrudes from the fourth region 541 of the second side surface 54 of the sealing resin 50. As viewed in the first direction z, the second outer portion 322 extends in the second direction x. The second outer portion 322 is bent in a gull wing shape as viewed in the third direction y. The shape of the second outer portion 322 is the same as the shape of the seventh outer portion 372 (see FIGS. 3 and 4) of each of the two seventh leads 37, described later. The surface of the second outer portion 322 may be plated with, for example, tin.

As shown in FIG. 7, the second outer portion 322 has a second attachment surface 322A. The second attachment surface 322A faces away from the second connection surface 321A of the second inner portion 321 in the first direction z. The second attachment surface 322A is located farthest from the second connection surface 321A in the first direction z. The second attachment surface 322A protrudes from the plane containing the bottom surface 52 of the sealing resin 50. The second attachment surface 322A is inclined with respect to the bottom surface 52.

As shown in FIGS. 1 and 2, the fourth lead 34 includes a portion extending toward the second die pad 22. The fourth lead 34 is connected to one side in the third direction y of the second die pad 22. The fourth lead 34 is spaced apart from each of the two third side surfaces 55. The fourth lead 34 has a fourth inner portion 341 and a fourth outer portion 342. The fourth inner portion 341 is connected to the second die pad 22 and covered with the sealing resin 50. The fourth outer portion 342 is connected to the fourth inner portion 341. The fourth outer portion 342 protrudes from the fourth region 541 of the second side surface 54 of the sealing resin 50. As viewed in the first direction z, the fourth outer portion 342 extends in the second direction x. The fourth outer portion 342 is bent in a gull wing shape as viewed in the third direction y. The shape of the fourth outer portion 342 is the same as the shape of the seventh outer portion 372 (see FIGS. 3 and 4) of each of the two seventh leads 37, described later. The surface of the fourth outer portion 342 may be plated with, for example, tin.

As shown in FIGS. 1 and 2, the sixth lead 36 includes a portion extending toward the second die pad 22. The sixth lead 36 is connected to the side in the third direction y of the second die pad 22 that is opposite to the side where the fourth lead 34 is located. The sixth lead 36 is spaced apart from each of the two third side surfaces 55. The sixth lead 36 has a sixth inner portion 361 and a sixth outer portion 362. The sixth inner portion 361 is connected to the second die pad 22 and covered with the sealing resin 50. The sixth outer portion 362 is connected to the sixth inner portion 361. The sixth outer portion 362 protrudes from the fourth region 541 of the second side surface 54 of the sealing resin 50. As viewed in the first direction z, the sixth outer portion 362 extends in the second direction x. The sixth outer portion 362 is bent in a gull wing shape as viewed in the third direction y. The shape of the sixth outer portion 362 is the same as the shape of the seventh outer portion 372 (see FIGS. 3 and 4) of each of the two seventh leads 37, described later.

As shown in FIG. 9, as viewed in the third direction y, each of the fourth inner portion 341 of the fourth lead 34 and the sixth inner portion 361 of the sixth lead 36 overlaps with the second die pad 22.

As shown in FIGS. 1 and 2, each of the two seventh leads 37 includes a portion extending toward the second die pad 22 and is located closest to one of the two third side surfaces 55 of the sealing resin 50. The two seventh leads 37 are spaced apart from each other in the third direction y. In the semiconductor device A10, the second leads 32, the fourth lead 34, and the sixth lead 36 are located between the two seventh leads 37. Each of the two seventh leads 37 is spaced apart from each of the first die pad 21, the second die pad 22 and the two third side surfaces 55. Each of the two seventh leads 37 has a seventh inner portion 371 and a seventh outer portion 372. The seventh inner portion 371 is covered with the sealing resin 50. The seventh outer portion 372 is connected to the seventh inner portion 371. The seventh outer portion 372 protrudes from the fourth region 541 of the second side surface 54 of the sealing resin 50. As viewed in the first direction z, the seventh outer portion 372 extends in the second direction x. As shown in FIGS. 3 and 4, the seventh outer portion 372 is bent in a gull wing shape as viewed in the third direction y. The surface of the seventh outer portion 372 may be plated with, for example, tin.

As shown in FIGS. 2 and 7, at least one of the first conductive members 41 is conductively bonded to one of the first electrodes 111 of the first semiconductor element 11 and the first connection surface 311A of the first inner portion 311 of one of the first leads 31. Thus, at least one of the first leads 31 is electrically connected to the first semiconductor element 11. At least one of the first conductive members 41 is conductively bonded to one of the first electrodes 111 and the third inner portion 331 of the third lead 33. Thus, the third lead 33 is electrically connected to the first semiconductor element 11. Also, at least one of the first conductive members 41 is conductively bonded to one of the first electrodes 111 and the fifth inner portion 351 of the fifth lead 35. Thus, the fifth lead 35 is electrically connected to the first semiconductor element 11. At least one of the third lead 33 and the fifth lead 35 provides the ground for the first semiconductor element 11.

As shown in FIG. 7, in the first direction z, the first conductive members 41 are located between the first mounting surface 21A of the first die pad 21 and the top surface 51 of the sealing resin 50. The first conductive members 41 are wires. The first conductive members 41 contain, for example, gold. Alternatively, each of the first conductive members 41 may be made of a core material containing copper and a coating material containing palladium and covering the core material.

As shown in FIGS. 2 and 7, at least one of the second conductive members 42 is conductively bonded to one of the second electrodes 121 of the second semiconductor element 12 and the second connection surface 321A of the second inner portion 321 of one of the second leads 32. Thus, at least one of the second leads 32 is electrically connected to the second semiconductor element 12. At least one of the second conductive members 42 is conductively bonded to one of the second electrodes 121 and the fourth inner portion 341 of the fourth lead 34. Thus, the fourth lead 34 is electrically connected to the second semiconductor element 12. At least one of the second conductive members 42 is conductively bonded to one of the second electrodes 121 and the sixth inner portion 361 of the sixth lead 36. Thus, the sixth lead 36 is electrically connected to the second semiconductor element 12. At least one of the fourth lead 34 and the sixth lead 36 provides the ground for the second semiconductor element 12. At least one of the second conductive members 42 is conductively bonded to one of the second electrodes 121 and the seventh inner portion 371 of one of the two seventh leads 37. Thus, at least one of the two seventh leads 37 is electrically connected to the second semiconductor element 12.

As shown in FIG. 7, in the first direction z, the second conductive members 42 are located between the second mounting surface 22A of the second die pad 22 and the top surface 51 of the sealing resin 50. The second conductive members 42 are wires. The second conductive members 42 contain, for example, gold. Alternatively, each of the second conductive members 42 may be made of a core material containing copper and a coating material containing palladium and covering the core material.

As shown in FIGS. 2 and 7, each of the third conductive members 43 is conductively bonded to one of the third electrodes 131 of the insulating element 13 and one of the first electrodes 111 of the first semiconductor element 11. Thus, the first semiconductor element 11 is electrically connected to the insulating element 13. The third conductive members 43 are arranged along the third direction y. Each of the third conductive members 43 extends across one of the second holes 212 formed in the first die pad 21.

As shown in FIGS. 2 and 7, each of the fourth conductive members 44 is conductively bonded to one of the fourth electrodes 132 of the insulating element 13 and one of the second electrodes 121 of the second semiconductor element 12. Thus, the second semiconductor element 12 is electrically connected to the insulating element 13. The fourth conductive members 44 are arranged along the third direction y. The fourth conductive members 44 extend across the space between the first die pad 21 and the second die pad 22.

As shown in FIG. 7, in the first direction z, each of the third and the fourth conductive members 43 and 44 is located between either the first mounting surface 21A of the first die pad 21 or the second mounting surface 22A of the second die pad 22 and the top surface 51 of the sealing resin 50. The third conductive members 43 and the fourth conductive members 44 are wires. The third conductive members 43 and the fourth conductive members 44 contain, for example, gold.

As shown in FIG. 7, in the first direction z, the distance L1 from the top surface 51 of the sealing resin 50 to any of the fourth conductive members 44 is shorter than the distance L2 from the top surface 51 to any of the third conductive members 43.

Generally, in motor driver circuits of inverter devices, a half-bridge circuit that includes a low-side (low-potential side) switching element and a high-side (high-potential side) switching element is configured. An example in which these switching elements are MOSFETs is described below. In the low-side switching element, the reference potentials of the source of the switching element and the gate driver that drives the switching element are both ground. On the other hand, in the high-side switching element, the reference potentials of the source of the switching element and the gate driver that drives the switching element both correspond to the potential at the output node of the half-bridge circuit. Because the potential at the output node changes in response to the operation of the high-side switching element and the low-side switching element, the reference potential of the gate driver that drives the high-side switching element changes. When the high-side switching element is ON, the reference potential is equivalent to the voltage applied to the drain of the high-side switching element (e.g., 600 V or higher). In semiconductor device A10, the ground of the first semiconductor element 11 and the ground of the second semiconductor element 12 are separated. Thus, when the semiconductor device A10 is used as a gate driver for driving the high-side switching element, a voltage equivalent to the voltage applied to the drain of the high-side switching element is transiently applied to the ground of the second semiconductor element 12.

Next, the effect and advantages of the semiconductor device A10 will be described.

The semiconductor device A10 includes the first die pad 21, the first semiconductor element 11, the first leads 31, the first conductive members 41, and the sealing resin 50. The first leads 31 protrude from the first side surface 53 of the sealing resin 50. The distance in the first direction z between the first mounting surface 21A of the first die pad 21 and the top surface 51 of the sealing resin 50 is defined as a first distance D1. The distance in the first direction z between the first reverse surface 21B of the first die pad 21 and the bottom surface 52 of the sealing resin 50 is defined as a second distance D2. The distance in the first direction z between the first element surface 11A of the first semiconductor element 11 and the top surface 51 is defined as a third distance D3. These satisfy the relationship D1>D2≥D3. Further, in the first direction z, the first conductive members 41 are located between the first mounting surface 21A and the top surface 51. With such a configuration, the thickness of the sealing resin 50 over the first conductive members 41 can be made larger without increasing the size of the sealing resin 50. Therefore, according to such a configuration of the semiconductor device A10, it is possible to prevent a decrease in the dielectric strength of the semiconductor device A10 without increasing the size of the semiconductor device A10.

The first side surface 53 of the sealing resin 50 includes the first region 531, the second region 532, and the third region 533. Each of the second region 532 and the third region 533 is inclined with respect to the first region 531. The first leads 31 protrude from the first region 531. The inclination angle α1 of the second region 532 with respect to the first region 531 is greater than the inclination angle β1 of the third region 533 with respect to the first region 531. With such a configuration, when forming the portion of sealing resin 50 located between the top surface 51 and the first mounting surface 21A of the first die pad 21 in the first direction z, damage to that portion is prevented from occurring during the removal of the molding die.

The semiconductor device A10 further includes the second die pad 22, the second semiconductor element 12, the second leads 32, and the second conductive members 42. The second leads 32 protrude from the second side surface 54 of the sealing resin 50. The distance in the first direction z between the second mounting surface 22A of the second die pad 22 and the top surface 51 of the sealing resin 50 is defined as a fourth distance D4. The distance in the first direction z between the second reverse surface 22B of the second die pad 22 and the bottom surface 52 of the sealing resin 50 is defined as a fifth distance D5. The distance in the first direction z between the second element surface 12A of the second semiconductor element 12 and the top surface 51 is defined as a sixth distance D6. These satisfy the relationship D4>D5≥D6. Further, in the first direction z, the second conductive members 42 are located between the second mounting surface 22A and the top surface 51. With such a configuration, the thickness of the sealing resin 50 over the second conductive members 42 can be made larger without increasing the size of the sealing resin 50. Thus, a decrease in the dielectric strength of the semiconductor device A10 is effectively prevented.

As viewed in the third direction y, each of the third lead 33 and the fifth lead 35 overlaps with the first die pad 21. With such a configuration, the molten resin can flow to each side in the first direction z of the first die pad 21 at a more uniform flow rate in the cavity of the molding die. This results in more dense filling of the sealing resin 50 at the portion that overlaps with the entirety of the first die pad 21 as viewed in the first direction z.

As viewed in the third direction y, each of the two seventh leads 37 overlaps with the second die pad 22. With such a configuration, the molten resin can flow to each side in the first direction z of the second die pad 22 at a more uniform flow rate in the cavity of the molding die. This results in more dense filling of the sealing resin 50 at the portion that overlaps with the entirety of the second die pad 22 as viewed in the first direction z.

The semiconductor device A10 further includes the insulating element 13, the third conductive members 43, and the fourth conductive members 44. In the first direction z, each of the third and the fourth conductive members 43 and 44 is located between either the first mounting surface 21A of the first die pad 21 or the second mounting surface 22A of the second die pad 22 and the top surface 51 of the sealing resin 50. With such a configuration, the thickness of the sealing resin 50 over the third conductive members 43 and the thickness of the sealing resin 50 over the fourth conductive members 44 can be made larger without increasing the size of the sealing resin 50. Thus, a decrease in the dielectric strength of the semiconductor device A10 is effectively prevented.

The first die pad 21 has two first holes 211 and second holes 212 each penetrating in the first direction z. The two first holes 211 are located on opposite sides of the first semiconductor element 11 in the third direction y. The second holes 212 are located between the first semiconductor element 11 and the insulating element 13 in the second direction x. With such a configuration, the molten resin passes through the two first holes 211 and the second holes 212 within the cavity of the molding die, which results in more dense filling of the sealing resin 50.

### Second embodiment:

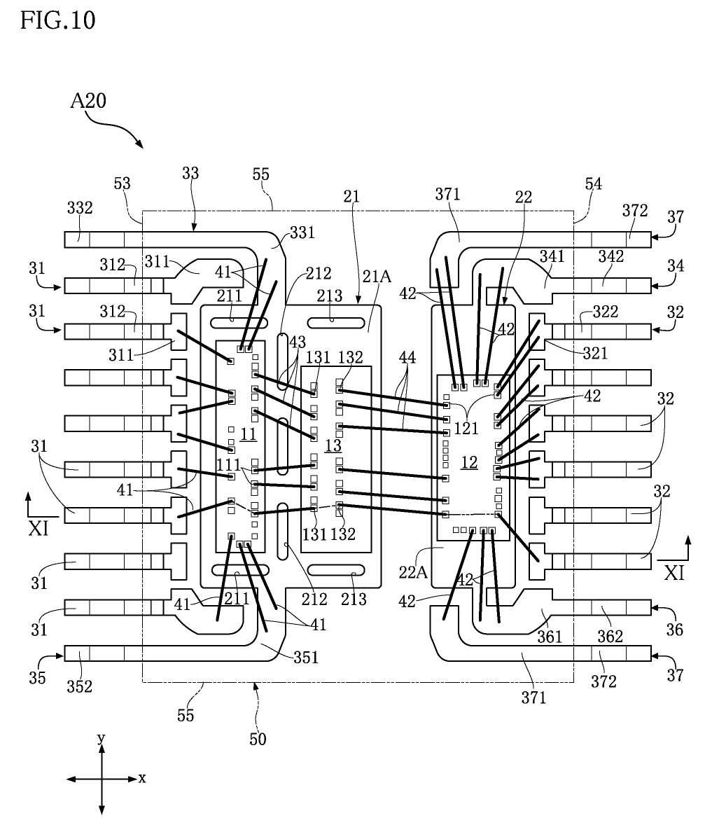

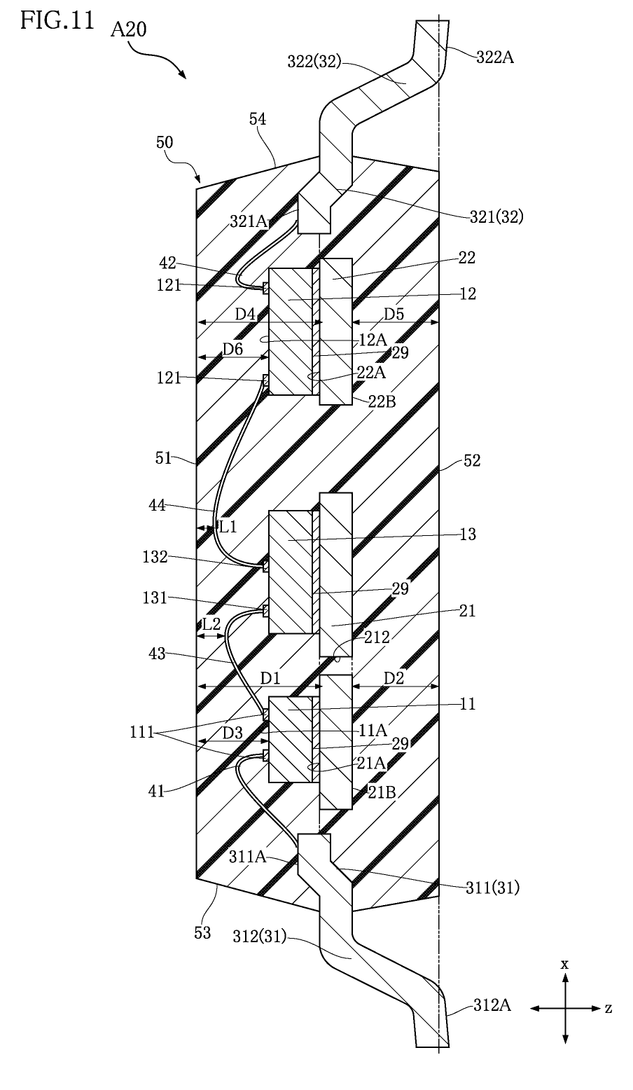

A semiconductor device A20 according to a second embodiment of the present disclosure will be described based on FIGS. 10 and 11. In these figures, the elements that are identical or similar to those of the semiconductor device A10 described above are denoted by the same reference signs, and the descriptions thereof are omitted. For convenience of understanding, the sealing resin 50 is transparent in FIG. 10. In FIG. 10, the outlines of the sealing resin 50 are shown by imaginary lines.

The semiconductor device A20 is different from the semiconductor device A10 in configuration of the first leads 31 and the second leads 32.

As shown in FIG. 11, the top surface 51 of the sealing resin 50 is located closer to the first connection surfaces 311A of the first leads 31 than to the first mounting surface 21A of the first die pad 21. Also, the top surface 51 is located closer to the second connection surfaces 321A of the second leads 32 than to the second mounting surface 22A of the second die pad 22.

Next, the effect and advantages of the semiconductor device A20 will be described.

The semiconductor device A20 includes the first die pad 21, the first semiconductor element 11, the first leads 31, the first conductive members 41, and the sealing resin 50. The first leads 31 protrude from the first side surface 53 of the sealing resin 50. The distance in the first direction z between the first mounting surface 21A of the first die pad 21 and the top surface 51 of the sealing resin 50 is defined as a first distance D1. The distance in the first direction z between the first reverse surface 21B of the first die pad 21 and the bottom surface 52 of the sealing resin 50 is defined as a second distance D2. The distance in the first direction z between the first element surface 11A of the first semiconductor element 11 and the top surface 51 is defined as a third distance D3. These satisfy the relationship D1>D2≥D3. Further, in the first direction z, the first conductive members 41 are located between the first mounting surface 21A and the top surface 51. Therefore, according to such a configuration of the semiconductor device A20, it is possible to prevent a decrease in the dielectric strength of the semiconductor device A20 without increasing the size of the semiconductor device A20. Furthermore, the semiconductor device A20 may have configurations in common with the semiconductor device A10 and hence may have the same advantages as the semiconductor device A10.

In the semiconductor device A20, the top surface 51 of the sealing resin 50 is located closer to the first connection surfaces 311A of the first leads 31 than to the first mounting surface 21A of the first die pad 21. Such a configuration allows shortening the first conductive members 41.

### Third embodiment:

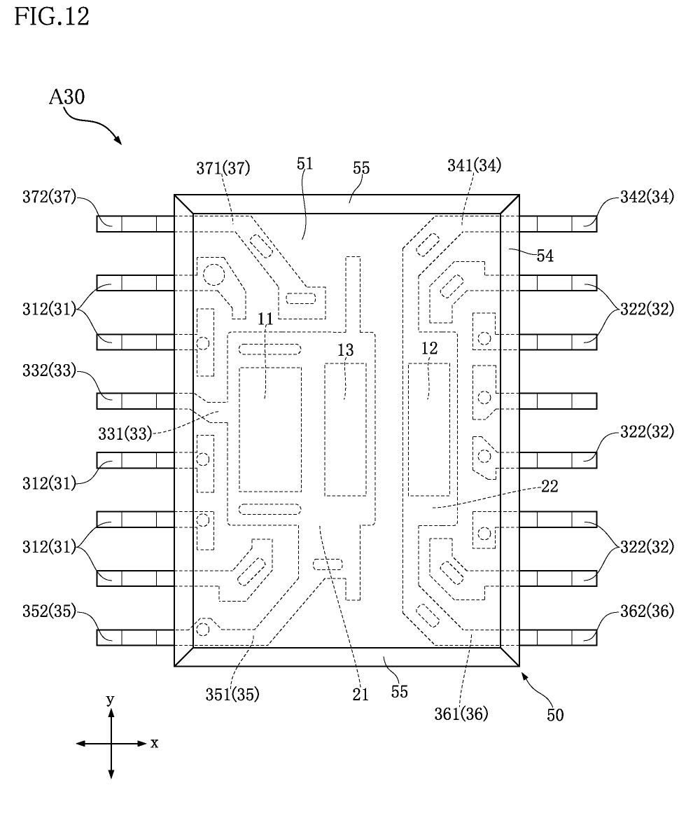

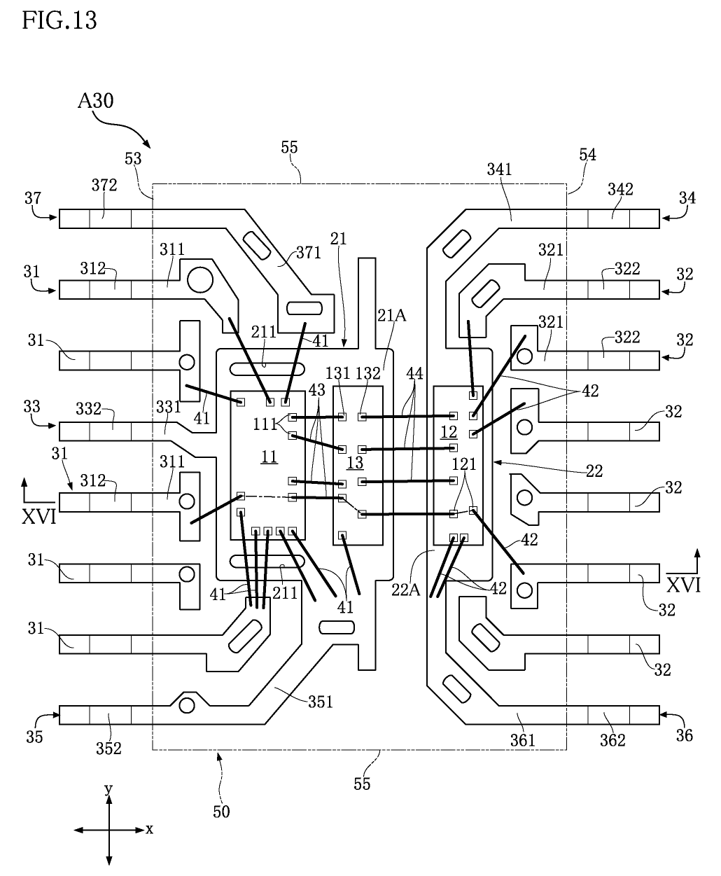

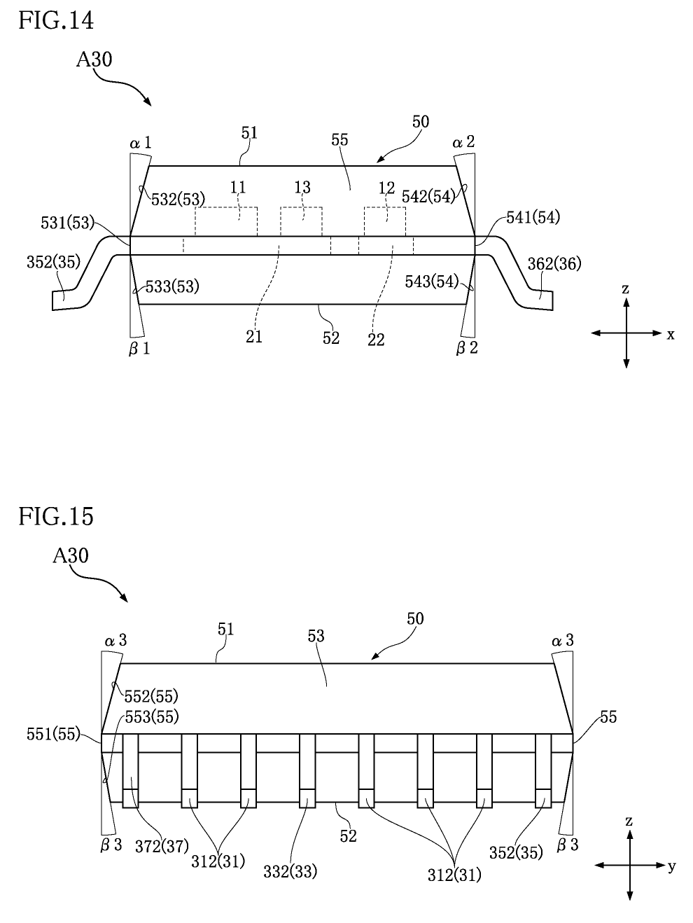

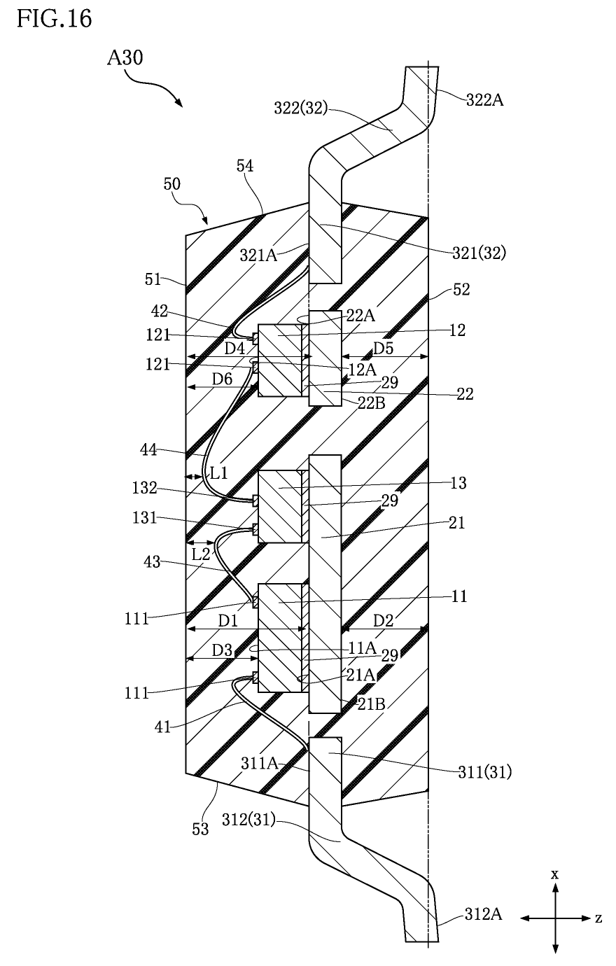

A semiconductor device A30 according to a third embodiment of the present disclosure will be described based on FIGS. 12 to 16. In these figures, the elements that are identical or similar to those of the semiconductor device A10 described above are denoted by the same reference signs, and the descriptions thereof are omitted. For convenience of understanding, the sealing resin 50 is transparent in FIG. 13. In FIG. 13, the outlines of the sealing resin 50 are shown by imaginary lines.

The semiconductor device A30 is different from the semiconductor device A10 in configuration of the third lead 33.

As shown in FIGS. 12 and 13, the third inner portion 331 of the third lead 33 is connected to one side in the second direction x of the first die pad 21. The third lead 33 is located between two of the plurality of first leads 31 in the third direction y. The third lead 33 is located opposite to the second die pad 22 with respect to the first die pad 21 in the second direction x.

As shown in FIGS. 12 and 13, the semiconductor device A30 includes a single seventh lead 37 instead of two seventh leads 37. The seventh lead 37 is located on one side in the third direction y of the first die pad 21. The first leads 31 and the third lead 33 are located between the seventh lead 37 and the fifth lead 35 in the third direction y.

Next, the effect and advantages of the semiconductor device A30 will be described.

The semiconductor device A30 includes the first die pad 21, the first semiconductor element 11, the first leads 31, the first conductive members 41, and the sealing resin 50. The first leads 31 protrude from the first side surface 53 of the sealing resin 50. The distance in the first direction z between the first mounting surface 21A of the first die pad 21 and the top surface 51 of the sealing resin 50 is defined as a first distance D1. The distance in the first direction z between the first reverse surface 21B of the first die pad 21 and the bottom surface 52 of the sealing resin 50 is defined as a second distance D2. The distance in the first direction z between the first element surface 11A of the first semiconductor element 11 and the top surface 51 is defined as a third distance D3. These satisfy the relationship D1>D2≥D3. Further, in the first direction z, the first conductive members 41 are located between the first mounting surface 21A and the top surface 51. Therefore, according to such a configuration of the semiconductor device A30, it is possible to prevent a decrease in the dielectric strength of the semiconductor device A30 without increasing the size of the semiconductor device A30. Furthermore, the semiconductor device A30 may have configurations in common with the semiconductor device A10 and hence may have the same advantages as the semiconductor device A10.

The present disclosure is not limited to the above-described embodiments. Various modifications in design may be made freely in the specific structure of each part of the present disclosure.

The present disclosure includes the embodiments described in the following clauses.

### Clause 1.

A semiconductor device comprising: a first die pad including a first mounting surface and a first reverse surface facing away from each other in a first direction; a first semiconductor element mounted on the first mounting surface; a first lead spaced apart from the first die pad; a first conductive member conductively bonded to the first semiconductor element and the first lead; and a sealing resin covering the first die pad, the first semiconductor element, and the first conductive member, wherein the first semiconductor element includes a first element surface facing the same side as the first mounting surface in the first direction, the sealing resin includes a top surface facing the same side as the first mounting surface in the first direction, a bottom surface facing away from the top surface in the first direction, and a first side surface facing one side in a second direction orthogonal to the first direction, the first lead protrudes from the first side surface, when a first distance in the first direction between the first mounting surface and the top surface is defined as D1, a second distance in the first direction between the first reverse surface and the bottom surface is defined as D2, and a third distance in the first direction between the first element surface and the top surface is defined as D3, a relationship D1>D2≥D3 is satisfied, and the first conductive member is located between the first mounting surface and the top surface in the first direction.

### Clause 2.

The semiconductor device according to clause 1, wherein the first side surface includes a first region extending in the first direction in-plane, a second region located between the first region and the top surface in the first direction, and a third region located opposite to the second region with respect to the first region, each of the second region and the third region is inclined with respect to the first region, the first lead protrudes from the first region, and an inclination angle of the second region with respect to the first region is greater than an inclination angle of the third region with respect to the first region.

### Clause 3.

The semiconductor device according to clause 2, wherein the first conductive member is a wire.

### Clause 4.

The semiconductor device according to clause 3, wherein the first lead includes a first connection surface facing the same side as the first mounting surface in the first direction, and the first conductive member is conductively bonded to the first connection surface.

### Clause 5.

The semiconductor device according to clause 4, wherein the first connection surface and the first mounting surface are contained in the same plane.

### Clause 6.

The semiconductor device according to clause 4, wherein the top surface is located closer to the first connection surface than to the first mounting surface.

### Clause 7.

The semiconductor device according to clause 4, wherein the first lead includes a first attachment surface exposed from the sealing resin and facing away from the first connection surface in the first direction, the first attachment surface is located farthest from the first connection surface in the first direction, and the first attachment surface protrudes from a plane containing the bottom surface.

### Clause 8.

The semiconductor device according to clause 7, wherein the first attachment surface is inclined with respect to the bottom surface.

### Clause 9.

The semiconductor device according to any one of clauses 1 to 8, further comprising: a second die pad including a second mounting surface facing the same side as the first mounting surface in the first direction, and a second reverse surface facing away from the second mounting surface in the first direction; a second semiconductor element mounted on the second mounting surface; a second lead spaced apart from the second die pad; and a second conductive member conductively bonded to the second semiconductor element and the second lead, wherein the second semiconductor element includes a second element surface facing the same side as the second mounting surface in the first direction, the sealing resin includes a second side surface facing away from the first side surface in the second direction, the second die pad, the second semiconductor element, and the second conductive member are covered with the sealing resin, the second lead protrudes from the second side surface, when a fourth distance in the first direction between the second mounting surface and the top surface is defined as D4, a fifth distance in the first direction between the second reverse surface and the bottom surface is defined as D5, and a sixth distance in the first direction between the second element surface and the top surface is defined as D6, a relationship D4>D5≥D6 is satisfied, and the second conductive member is located between the second mounting surface and the top surface in the first direction.

### Clause 10.

The semiconductor device according to clause 9, wherein the second conductive member is a wire.

### Clause 11.

The semiconductor device according to clause 10, further comprising a third lead connected to the first die pad, wherein the third lead protrudes from the first side surface.

### Clause 12.

The semiconductor device according to clause 11, wherein the sealing resin includes two third side surfaces spaced apart from each other in a third direction orthogonal to each of the first direction and the second direction, and the third lead is spaced apart from each of the two third side surfaces.

### Clause 13.

The semiconductor device according to clause 12, wherein the third lead is connected to one side in the second direction of the first die pad.

### Clause 14.

The semiconductor device according to clause 12, further comprising a fourth lead connected to the second die pad, wherein the fourth lead protrudes from the second side surface.

### Clause 15.

The semiconductor device according to clause 14, wherein the fourth lead is spaced apart from each of the two third side surfaces.

### Clause 16.

The semiconductor device according to clause 15, further comprising: an insulating element mounted on the first mounting surface; a third conductive member conductively bonded to the insulating element and the first semiconductor element; and a fourth conductive member conductively bonded to the insulating element and the second semiconductor element, wherein in the first direction, each of the third conductive member and the fourth conductive member is located between either the first mounting surface or the second mounting surface and the top surface, and each of the third conductive member and the fourth conductive member is a wire.

### Clause 17.

The semiconductor device according to clause 16, wherein in the first direction, a distance from the top surface to the fourth conductive member is shorter than a distance from the top surface to the third conductive member.

1. A semiconductor device comprising:
a first die pad including a first mounting surface and a first reverse surface facing away from each other in a first direction;
a first semiconductor element mounted on the first mounting surface;
a first lead spaced apart from the first die pad;
a first conductive member conductively bonded to the first semiconductor element and the first lead; and
a sealing resin covering the first die pad, the first semiconductor element, and the first conductive member, wherein
the first semiconductor element includes a first element surface facing the same side as the first mounting surface in the first direction,
the sealing resin includes a top surface facing the same side as the first mounting surface in the first direction, a bottom surface facing away from the top surface in the first direction, and a first side surface facing one side in a second direction orthogonal to the first direction,
the first lead protrudes from the first side surface,
when D1 is a first distance in the first direction between the first mounting surface and the top surface, D2 is a second distance in the first direction between the first reverse surface and the bottom surface, and D3 is a third distance in the first direction between the first element surface and the top surface, a relationship D1>D2≥D3 is satisfied, and
the first conductive member is located between the first mounting surface and the top surface in the first direction.

2. The semiconductor device according to claim 1, wherein the first side surface includes a first region extending in the first direction in-plane, a second region located between the first region and the top surface in the first direction, and a third region located opposite to the second region with respect to the first region,
each of the second region and the third region is inclined with respect to the first region,
the first lead protrudes from the first region, and
an inclination angle of the second region with respect to the first region is greater than an inclination angle of the third region with respect to the first region.

3. The semiconductor device according to claim 2, wherein the first conductive member is a wire.

4. The semiconductor device according to claim 3, wherein the first lead includes a first connection surface facing the same side as the first mounting surface in the first direction, and
the first conductive member is conductively bonded to the first connection surface.

5. The semiconductor device according to claim 4, wherein the first connection surface and the first mounting surface are contained in the same plane.

6. The semiconductor device according to claim 4, wherein the top surface is located closer to the first connection surface than to the first mounting surface.

7. The semiconductor device according to claim 4, wherein the first lead includes a first attachment surface exposed from the sealing resin and facing away from the first connection surface in the first direction,
the first attachment surface is located farthest from the first connection surface in the first direction, and
the first attachment surface protrudes from a plane containing the bottom surface.

8. The semiconductor device according to claim 7, wherein the first attachment surface is inclined with respect to the bottom surface.

9. The semiconductor device according to claim 1, further comprising:
a second die pad including a second mounting surface facing the same side as the first mounting surface in the first direction, and a second reverse surface facing away from the second mounting surface in the first direction;
a second semiconductor element mounted on the second mounting surface;
a second lead spaced apart from the second die pad; and
a second conductive member conductively bonded to the second semiconductor element and the second lead, wherein
the second semiconductor element includes a second element surface facing the same side as the second mounting surface in the first direction,
the sealing resin includes a second side surface facing away from the first side surface in the second direction,
the second die pad, the second semiconductor element, and the second conductive member are covered with the sealing resin,
the second lead protrudes from the second side surface,
when a fourth distance in the first direction between the second mounting surface and the top surface is D4, a fifth distance in the first direction between the second reverse surface and the bottom surface is D5, and a sixth distance in the first direction between the second element surface and the top surface is D6, a relationship D4>D5≥D6 is satisfied, and
the second conductive member is located between the second mounting surface and the top surface in the first direction.

10. The semiconductor device according to claim 9, wherein the second conductive member is a wire.

11. The semiconductor device according to claim 10, further comprising a third lead connected to the first die pad,
wherein the third lead protrudes from the first side surface.

12. The semiconductor device according to claim 11, wherein the sealing resin includes two third side surfaces spaced apart from each other in a third direction orthogonal to each of the first direction and the second direction, and
the third lead is spaced apart from each of the two third side surfaces.

13. The semiconductor device according to claim 12, wherein the third lead is connected to one side in the second direction of the first die pad.

14. The semiconductor device according to claim 12, further comprising a fourth lead connected to the second die pad,
wherein the fourth lead protrudes from the second side surface.

15. The semiconductor device according to claim 14, wherein the fourth lead is spaced apart from each of the two third side surfaces.

16. The semiconductor device according to claim 15, further comprising:
an insulating element mounted on the first mounting surface;
a third conductive member conductively bonded to the insulating element and the first semiconductor element; and
a fourth conductive member conductively bonded to the insulating element and the second semiconductor element, wherein
in the first direction, each of the third conductive member and the fourth conductive member is located between either the first mounting surface or the second mounting surface and the top surface, and
each of the third conductive member and the fourth conductive member is a wire.

17. The semiconductor device according to claim 16, wherein in the first direction, a distance from the top surface to the fourth conductive member is shorter than a distance from the top surface to the third conductive member.
